(19) United States
(12) Patent Application Publication
(10) Pub. No.: US 2011/0165737 A1
(43) Pub. Date: Jul. 7, 2011

(54) Method for designing semiconductor integrated circuit which includes metallic wiring connected to gate electrode and satisfies antenna criterion

(75) Inventor: Kenichi Yoda, Kanagawa (JP)

(73) Assignee: RENESAS ELECTRONICS CORPORATION, Kawasaki-shi (JP)

(21) Appl. No.: 13/064,254

(22) Filed: Mar. 14, 2011

Related U.S. Application Data
(62) Division of application No. 12/458,150, filed on Jul. 1, 2009.

(30) Foreign Application Priority Data
Jul. 3, 2008 (JP) 2008-174483

(51) Int. Cl. H01L 21/82

(52) U.S. Cl. 438/129; 257/E21.602

(57) ABSTRACT

A method of forming a semiconductor integrated circuit, includes providing a first logic cell, a second logic cell and a metallic wiring connected to the first logic cell and a gate electrode of the second logic cell, and providing a third logic cell including a gate electrode connected to the metallic wiring, such that the third logic cell makes no contribution to a logic operation of the semiconductor integrated circuit, in order that an antenna ratio of the first gate electrode to the metallic wiring does not satisfy an antenna criterion, and an antenna ratio of the first gate electrode and the second gate electrode to the metallic wiring satisfies the antenna criterion.

The present Application is a Divisional Application of U.S. patent application Ser. No. 12/458,150, filed on Jul. 1, 2009.

### INCORPORATION BY REFERENCE

This application is based upon and claims the benefit of priority from Japanese Patent Application No. 2008-174483 which was filed on Jul. 3, 2008, the disclosure of which is incorporated herein in its entirety by reference.

### BACKGROUND OF THE INVENTION

1. Field of the Invention

The present invention relates to a method for designing a semiconductor integrated circuit whereby plasma damage to a gate insulating film is avoided by improving an antenna ratio, a manufacture method, and a circuit design program product.

2. Description of Related Art

In the manufacture of thin film devices of semiconductor integrated circuits, many plasma processes, such as etching, ashing, ion implantation, and plasma CVD (Chemical Vapor Deposition), are used. In such plasma processes, break down and damages of the gate insulating film caused by a charge up phenomenon (the plasma damage) have become problems. The plasma damage occurs as follows: an electric conductive body (e.g., metallic wiring) that becomes exposed in the plasma captures charged particles in the plasma, and captured electric charges reach a gate electrode of a transistor. For example, in an etching process of forming signal wiring, the signal wiring acts as an antenna for capturing the electric charges from the plasma. A charge current by the electric charges captured by the signal wiring concentrates in the gate insulating film through the gate electrode and damages the gate insulating film.

Since a size of the plasma damage is determined according to a current density of the charge current flowing through the gate insulating film, it becomes possible to lighten the plasma damage in a manufacture process by controlling an area of the metallic wiring and an area of the gate electrode that function as antennae. In detail, when designing a semiconductor integrated circuit, a layout pattern is designed so that the antenna ratio may become smaller than or equal to a predetermined threshold (antenna criterion). Here, the antenna ratio represents a ratio of an area of the signal wiring (the metallic wiring) connected to a gate relative to an area of the gate electrode (a gate area) in the transistor. Usually, it is verified, in pattern verification after the layout design of a semiconductor integrated circuit, whether the antenna ratio satisfies the antenna criterion. When the antenna ratio exceeds the antenna criterion (an antenna error), the layout pattern is corrected so that the antenna ratio may satisfy the antenna criterion. Such pattern verification and layout correction make it possible to design the semiconductor integrated circuit that is less prone to the plasma damage in the manufacture process.

The layout correction methods each of which is performed in order to lighten the plasma damage are described, for example, in Japanese Patent Application Laid Open No.

### 2000-106419 (Patent Document 1), Japanese Patent Application Laid Open No.

### 2007-317814 (Patent Document 2), Japanese Patent Application Laid Open No.

### 2001-223275 (Patent Document 3), and Japanese Patent Application Laid Open No.

### 2007-293822 (Patent Document 4).

Patent Document 1 describes a design method of a semiconductor integrated circuit such that a protective diode cell having a protective diode for bypassing the charge current that concentrates in the gate electrode is prepared in advance and the protective diode cell is connected to a cell that was determined as the antenna error, and thereby, the antenna error is eliminated. However, Patent Document 1 need to newly insert a protective diode cell. Therefore, when a coverage ratio of standard cells is high and no free region exists, the area of the semiconductor integrated circuit will increase.

On the other hand, Patent Document 2 discloses a technology to avoid the antenna error by a standard cell which includes a protective diode inserted into the free region inside the cell. Therefore, it is possible to manufacture the semiconductor integrated device in which the plasma damage is lightened without increasing the area as is the case of Patent Document 1. However, using the standard cell which includes the protective diode will produce a problem which increases an input capacitance.

In addition, there is a technology of eliminating the antenna error by correcting the wiring area and the gate area, not using the protective diode. For example, a method altering a layout of a wiring layer can be used to make the antenna ratio small and, resulting in decreasing the wiring area as a general measure against the antenna error. However, in a process that is minimized in the recent years, since the gate area is minute, even if the gate area is changed, the antenna ratio will hardly sufficiently change. In order to avoid the antenna error by reducing the wiring area, considerable correction of the layout will be needed.

Therefore, a method to make the antenna ratio small by increasing the gate area as described in Patent Document 3 and Patent Document 4 is effective.

Patent Document 3 describes a method whereby the gate area connected to the wiring is increased by insertion of a buffer on the wiring that was determined to have the antenna error, and consequently the antenna ratio is made small.

FIGS. 1A to 2B illustrate a method for designing a semiconductor device described in Patent Document 3. FIG. 1A is a plan view showing one example of a circuit that is subject to the pattern verification. FIG. 1B is an equivalent circuit diagram of the circuit shown in FIG. 1A. Referring to FIG. 1A and FIG. 1B, an output end of a preceding stage logic cell 10 and an input end of a subsequent stage logic cell 20 are connected together through the metallic wiring. In the pattern verification, it is verified whether the antenna ratio of the gate electrode and the metallic wiring in the subsequent stage logic cell 20 satisfies the antenna criterion.

FIG. 2A is a plan view showing one example of a circuit whose layout is corrected by a method described in Patent Document 3. FIG. 2B is an equivalent circuit diagram of the circuit of FIG. 2A. Referring to FIG. 2A and FIG. 2B, when the circuit shown in FIG. 1A is determined to sustain the antenna error, a buffer cell 50 is inserted between the preceding stage logic cell 10 and the subsequent stage logic cell 20 by the method described in Patent Document 3. In this case, the wiring area used for computation of the antenna ratio becomes an area of the wiring from the output end of the preceding stage logic cell 10 to the input end of the buffer cell 50. Moreover, the gate area used for computation of the antenna ratio becomes a sum of the gate area in the subsequent stage logic cell 20 and the gate area in the buffer cell 50. That is, since the wiring area decreases and the gate area increases compared with the circuit shown in FIG. 1A, the antenna ratio decreases largely.

Moreover, Patent Document 3 and Patent Document 4 describe manufacture methods of semiconductor devices each of which avoids the antenna error by replacing a cell that was determined to sustain the antenna error with a cell whose gate area is large.

FIG. 3A is a plan view showing one example of a circuit whose layout was corrected by the method described in Patent Document 4. FIG. 3B is an equivalent circuit diagram of the circuit of FIG. 3A. Referring to FIG. 3A and FIG. 3B, by the method described in Patent Document 4, when the circuit shown in FIG. 1A is determined to sustain the antenna error, the subsequent stage logic cell 20 shown in FIG. 1A is replaced by a logic cell 60 that is the same logic as the subsequent stage logic cell 20 and has a larger gate area. In this case, although the wiring area does not change, the gate area becomes larger, and therefore the antenna ratio can be decreased more largely than in the case where only the wiring area is decreased.

As the above, by the layout correction that increases the gate area, the antenna ratio can be decreased effectively, and consequently the plasma damage can be lightened.

### SUMMARY

However, since a method described in Patent Document 3 inserts the buffer cell 50 in wiring, it is necessary to change an arrangement of other cells and wiring lengths. Since this constraint makes it difficult to predict a delaying amount of the signal wiring after alteration of the layout, there is an increased possibility that it causes a timing error in a timing verification phase.

Moreover, by a method for improving the antenna ratio by replacing the logic cell, in the case where the arrangement location of the logic cell after the replacement is the same as the arrangement location of the original subsequent stage logic cell, a load capacity of the logic cell after the replacement does not change compared with the original logic cell and its driving capability is increased. For this reason, the delay time of the signal at a signal path after the replaced logic cell will become short. Moreover, as shown in FIG. 3A, when the size of a logic cell 60 after replacement is different from that of an original subsequent stage logic cell 20, the arrangement location of the cell needs to be changed. Since arrangement and wiring length of the cells is changed, it becomes difficult to predict the delaying amount, and therefore possibility of the timing error increases.

When the timing error arises, repair processing, must be done, and consequently operation man hour and TAT (Turn Around Time) increase.

A method of designing a semiconductor integrated circuit, includes verifying an antenna ratio of a metallic wiring connected to a first gate electrode and the first gate electrode, based on a layout information, and computing a gate area that should be added to avoid a plasma damage to the first gate electrode, based on the verifying. The method further includes modifying a layout of the semiconductor integrated circuit, based on the computing, by arranging a logic cell having a second gate electrode having the gate area or more and is in state where the logic cell has no contribution to a logic operation of the semiconductor integrated circuit, in a free region of the layout, and connecting the second gate electrode to the metallic wiring.

In this way, since the gate area is increased by insertion of a logic cell that performs no logic operation into the free region, it is possible to improve the antenna ratio without altering other elements (logic cell arrangement and wiring) in a design object circuit.

It is desirable that the above-mentioned design method is implemented by a circuit design program that the computer executes.

The semiconductor integrated circuit is equipped with a first logic cell, a second logic cell, and the third logic cell. The first gate electrode in the first logic cell, the second logic cell, and the second gate in the third logic cell are connected together through the metallic wiring, and the third logic cell makes no contribution to the logic operations of the semiconductor integrated circuit. The gate area connected to the metallic wiring that functions as an antenna in the plasma process is enlarged by the second gate electrode. For this reason, the antenna ratio of the first gate electrode and the metallic wiring becomes less than or equal to an antenna criterion, which realizes a semiconductor integrated circuit in which plasma damage in the plasma process was lightened. The second gate electrode of the third logic cell that performs no logic operations is connected to a metal cell between the logic cells. Since the logic cell that performs no logic operations can be arranged in the free region, the third logic cell for improving the antenna ratio can be arranged without largely altering the layout.

According to a design method of a semiconductor integrated circuit, a manufacture method, and a manufacturing program, the plasma damage of the semiconductor integrated circuit can be lightened while controlling delay variation caused by layout correction. In addition, the plasma damage of the semiconductor integrated circuit can be controlled without increasing a circuit area.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1A is a plan view showing one example of a circuit that is subject to pattern verification and FIG. 1B is an equivalent circuit diagram of the circuit shown in FIG. 1A;

FIG. 2A is a plan view showing one example of a circuit layout which improves an antenna ratio by a related technology and FIG. 2B is an equivalent circuit diagram of the circuit of FIG. 2A;

FIG. 3A is a plan view showing one example of a circuit layout which improves the antenna ratio by another related technology and FIG. 3B is an equivalent circuit diagram of the circuit of FIG. 3A;

FIG. 4 is a diagram showing a configuration of a design support system according to the present invention;

FIG. 5 is a diagram showing one example of a gate area table;

FIG. 6 is a functional block diagram in an exemplary embodiment of the design support system according to the present invention;

FIG. 7 is a plan view showing a part of a layout pattern of a design object circuit that has been put into chip layout according to the present invention;

FIG. 8 is an A-A′ sectional view in FIG. 7.

FIG. 9 is a flow chart showing a layout corrective action in the exemplary embodiment of the design support system in the present invention;

FIG. 10 is a plan view showing a part of the layout pattern of the design object circuit after layout correction according to the present invention;

FIG. 11 is A-A′ and A-B sectional views in FIG. 10;

FIG. 12 is a circuit diagram showing an equivalent circuit after the layout correction;

FIG. 13 is a diagram showing one example of the layout pattern of an inverter cell registered in a cell library; and

FIG. 14 is a flow chart showing one example of a layout correction operation in an exemplary embodiment of the design support system in the present invention.

### DETAILED DESCRIPTION OF THE EXEMPLARY EMBODIMENTS

### (Outline of the Present Invention)

The design support system 100 verifies an antenna ratio of each transistor in a design object circuit after the chip layout in a layout phase, and corrects the layout according to the verification result. When it is determined that the antenna verification results in an antenna error in antenna ratio verification, the design support system 100 computes a gate area required in order that the antenna ratio may satisfy a predetermined criterion value (an antenna criterion), and adds a logic cell having this gate area to the design object circuit. The design support system 100 inserts the logic cell in a free region, being in a state where the logic cell to be added performs no logic operations (e.g., the output end is in an open state). A gate electrode of the transistor inside the logic cell inserted into the free region is connected to the wiring that was determined to sustain the antenna error.

In this way, since the logic cell that performs no logic operation is inserted into the free region, the antenna ratio can be improved without altering other elements (logic cell arrangement and wiring) in the design object circuit. Therefore, there is no considerable alteration in timing by layout correction in order to eliminate the antenna error (to lighten the plasma damage).

### (Configuration of Design Support System 100)

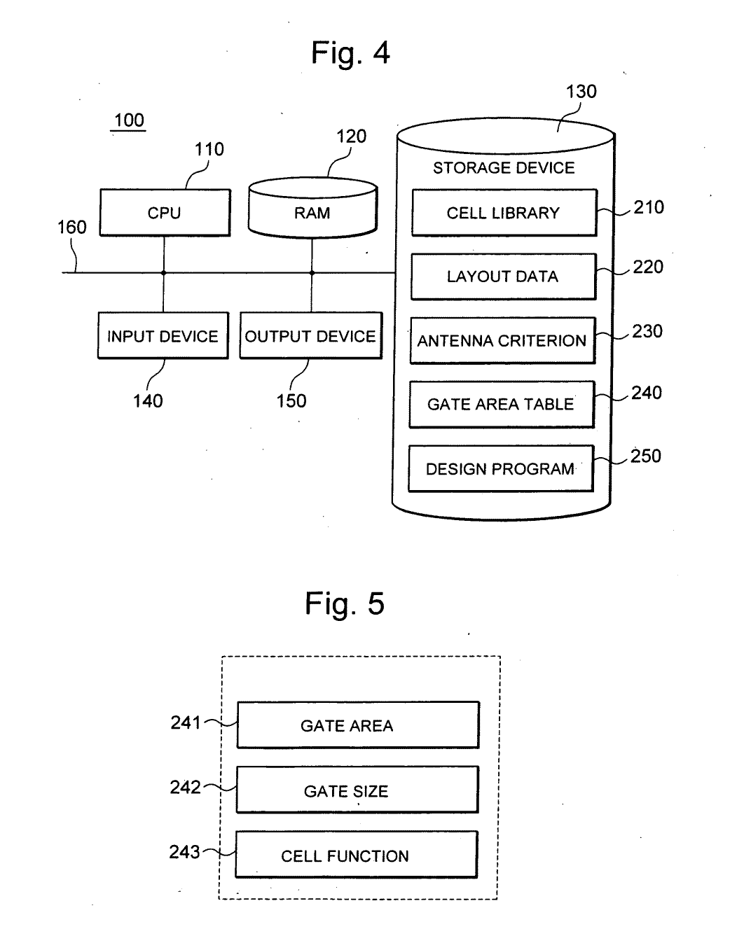

With reference to FIG. 4 to FIG. 6, a configuration of a design support system 100 in an exemplary embodiment according to the present invention will be described. FIG. 4 is a diagram showing the configuration of the design support system 100. The design support system 100 is equipped with a CPU 110, RAM 120, a storage device 130, an input device 140, and an output device 150 all of that are mutually connected through a bus 160. The storage device 130 is an external storage device, such as a hard disk drive and memory. Moreover, the input device 140 outputs various pieces of data to the CPU 110 and the storage device 130 by being operated by a user with a keyboard, a mouse, etc. The output device 150 is exemplified by a monitor and a printer, and outputs a layout result of the semiconductor integrated circuit outputted from the CPU 110 and the various pieces of information to the user in such a manner that the user can visually check it. The design support system 100 performs chip layout (arrangement of logic cells and wiring inside a chip).

The storage device 130 stores a cell library 210, layout data 220, an antenna criterion 230, a gate area table 240, and a design program 250.

The cell library 210 includes information about the logic cell that has been laid out in advance based on product specifications etc. The logic cell is equipped with a primitive cell (standard cell) having a basic logic circuit that is exemplified by an inverter, an AND gate, etc. and a macro cell having a large scale circuit that is exemplified by a counter, an adder, RAM, etc. The cell library 210 includes information about the layout and performance of the logic cell (a cell size, a transistor count, the gate area, etc.).

The layout data 220 includes information about the chip layout after the layout design. In detail, the layout data 220 includes arrangement information of the logic cell on the semiconductor integrated circuit after the layout, connection information of the wiring between logic cells, and information about positions and sizes of the free regions when the logic cell is not arranged.

The antenna criterion 230 is a threshold prescribed as a criterion for determining whether the cell sustains the antenna error in the pattern verification (the antenna ratio verification) of the semiconductor integrated circuit. For example, if the antenna ratio computed in the antenna ratio verification is larger than the antenna criterion 230, then it is determined that there is a high possibility that characteristic deterioration of the transistor and gate break down by plasma damage occur in a manufacture process. Therefore, it is desirable that the antenna ratio corresponding to a maximum value of permissible plasma damage for product specifications is set up as the antenna criterion 230.

The gate area table 240 is a table for sorting the logic cells included in the cell library 210 in terms of gate area of the internal transistors. FIG. 5 is a diagram showing one example of the gate area table 240. Referring to FIG. 5, the gate area table 240 records a gate area 241 in the logic cell, a cell size 242, and a cell function 243 that indicates the kind of a circuit element (e.g., inverter) in the logic cell, being correlated with one another. Referring to the gate area table 240 makes it easy to select the logic cell for the purpose of compensating the gate area (insufficient quantity) that is insufficient. Moreover, since the gate area 241 and the cell size 242 are correlated, the size of the free region required to secure the gate area can be checked easily. Regarding the logic cells to be registered in the gate area table 240, either all of the logic cells registered in the cell library 210 or a part thereof may be used.

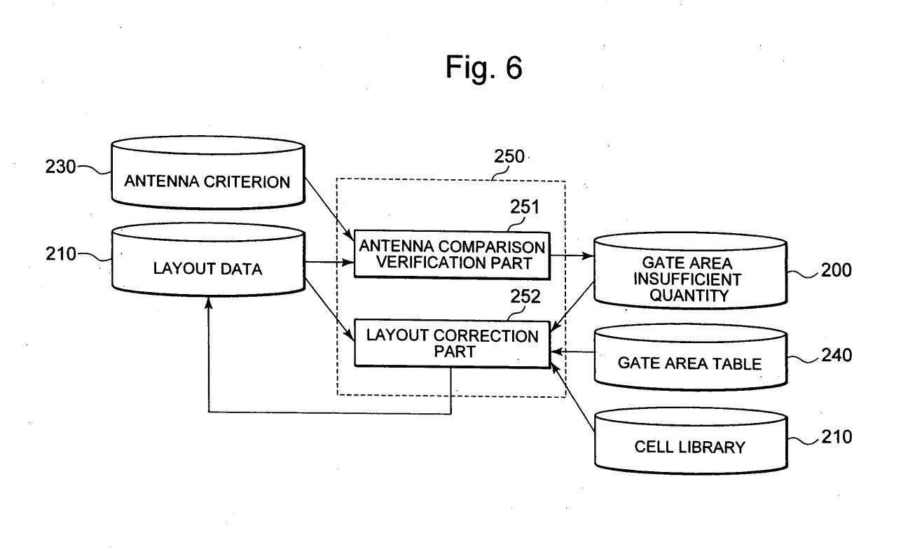

In response to an input from the input device 140, the CPU 110 executes the design program 250 in the storage device 130, and performs the verification of a layout pattern of the design object circuit (the antenna ratio verification) and the layout correction, in order to temporarily store various pieces of data and programs from the storage device 130 in the RAM 120. The CPU 110 performs various processions using the data in the RAM 120. Referring to FIG. 6, by the CPU 11 executing the design program 250, functions of an antenna ratio verification part 251 and a layout correction part 252 are realized, respectively.

FIG. 6 is a functional block diagram in the exemplary embodiment of the design support system 100. Referring to FIG. 6, based on the antenna criterion 230 and the layout data 220, the antenna ratio verification part 251 performs the antenna ratio verification to the each transistor in the design object circuit that has been laid out. When the transistor is determined to sustain the antenna error, the antenna ratio verification part 251 computes the gate area required to make the antenna ratio smaller than or equal to antenna criterion 230 as a gate area insufficient quantity 200.

The layout correction part 252 corrects the layout of the design object circuit according to the result of the antenna ratio verification. The layout correction part 252 decides a logic cell to be added and inserted and its insertion position using a position and a size of the free region that was specified from the layout data 220 and the gate area insufficient quantity 200, and thereby, corrects the layout. It is therefore desirable that the layout correction part 252 decides the logic cell to be added referring to the gate area table 240.

### (Operations of Design Support System 100)

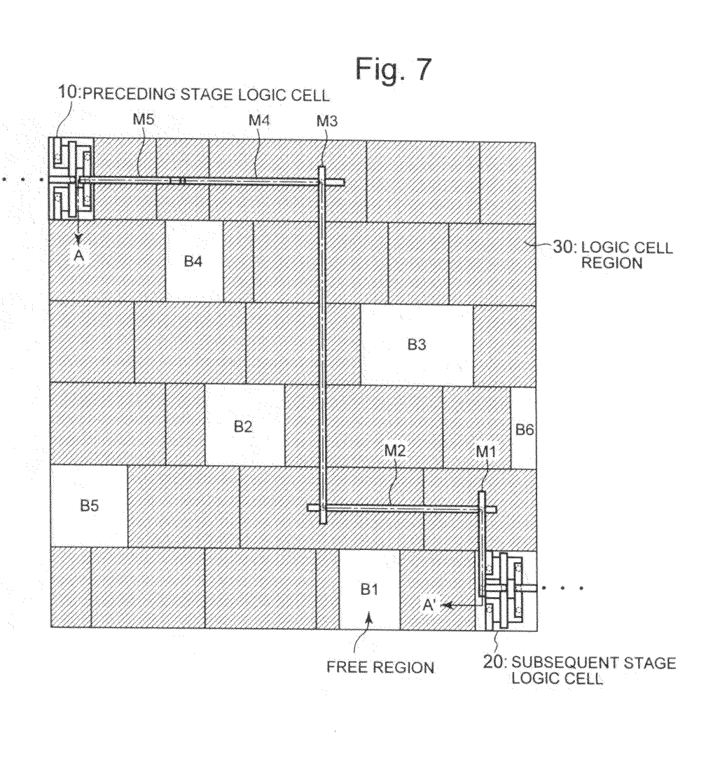

Next, with reference to FIG. 7 to FIG. 12, an antenna ratio verification operation and a layout corrective action in the exemplary embodiment of the design support system 100 according to the present invention will be described.

Prior to the layout correction, the design support system 100 verifies the antenna ratio of the design object circuit in which chip layout has been done. The verification of the antenna ratio is performed for the each transistor (gate) in the design object circuit. Below, the antenna ratio verification for the transistor in a subsequent stage logic cell 20 (an inverter cell) shown in FIG. 7 and the layout correction according to the antenna ratio verification result will be explained, as one example.

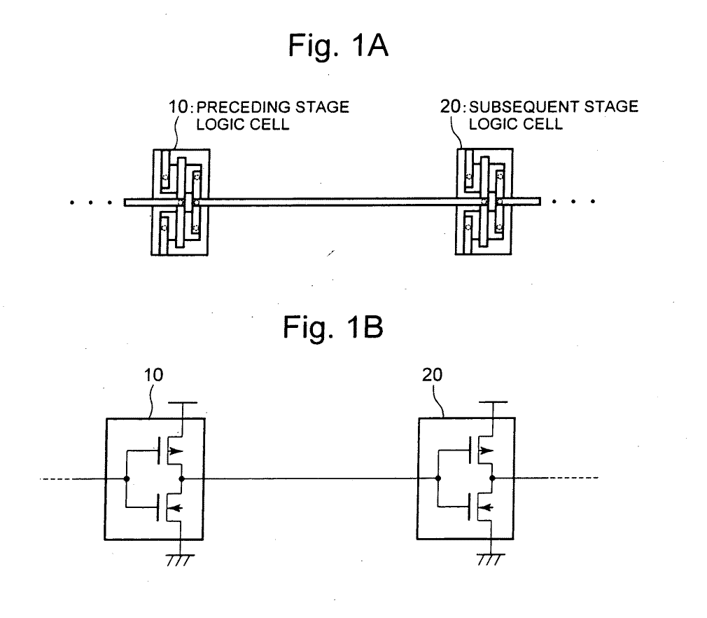

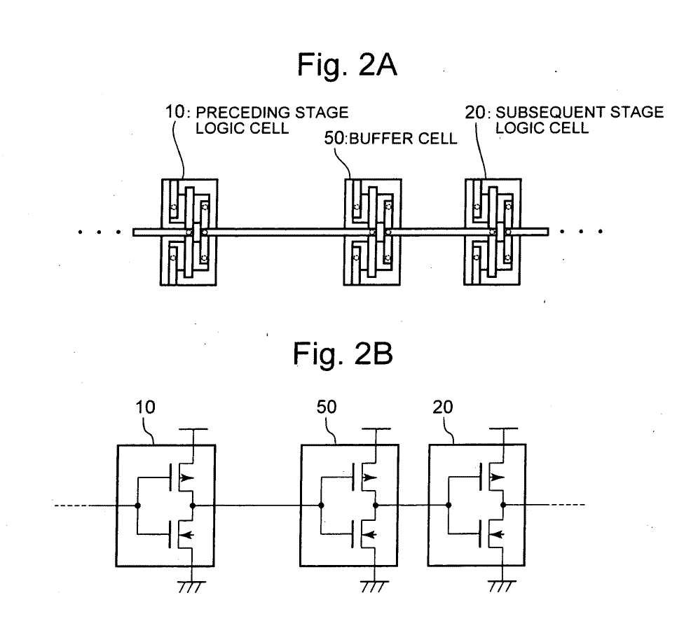

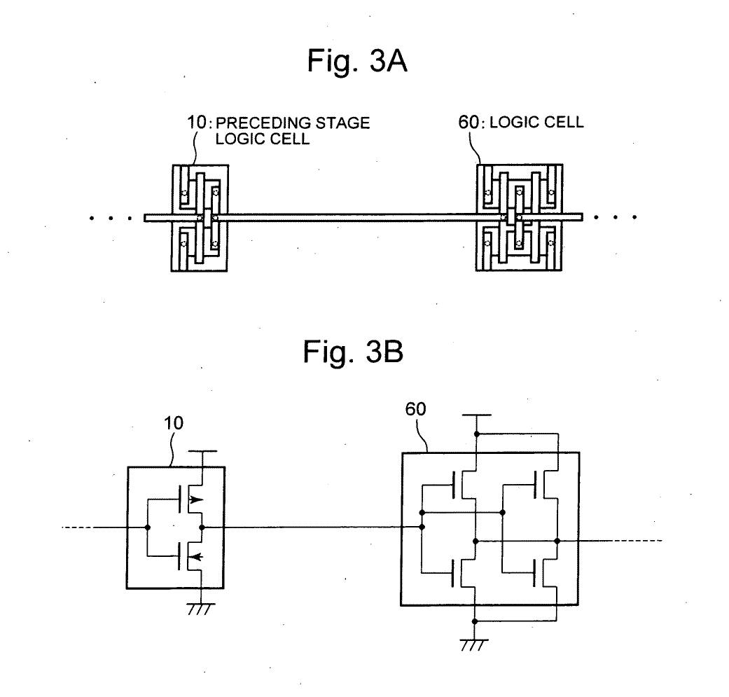

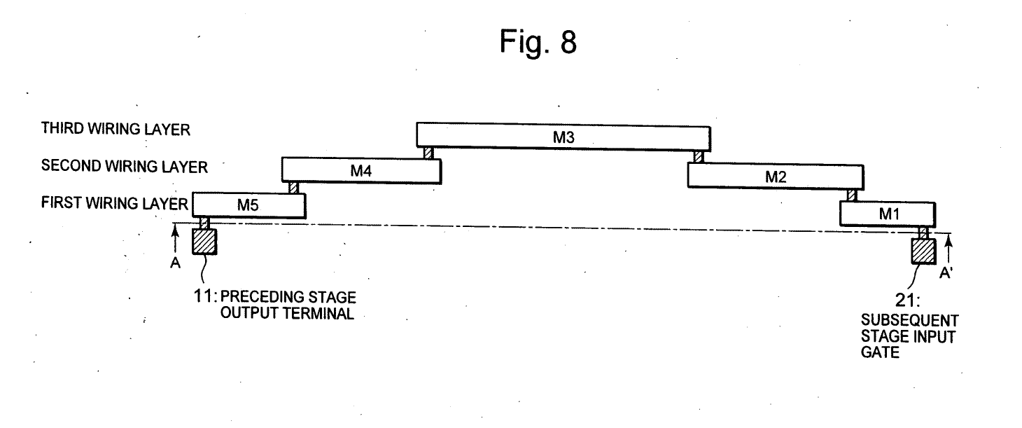

FIG. 7 is a plan view showing a part of the layout pattern of the design object circuit that is subjected to the chip layout. FIG. 8 is an A-A′ sectional view in FIG. 7. Referring to FIG. 7, the design support system 100 verifies the antenna ratio by setting a preceding stage logic cell 10 (a second logic cell) and the subsequent stage logic cell 20 (the first logic cell) that are connected together through metallic wiring M1 to M5 as a verification object circuit. An equivalent circuit of the verification object circuit is the same as that of FIG. 1B. Incidentally, although being omitted in FIG. 7, other wiring (logic cell) may be connected to the input end of the preceding stage logic cell 10 and the output end of the subsequent stage logic cell.

Referring to FIG. 8, the metallic wiring M1 to M5 is formed in a first wiring layer, a second wiring layer, and a third wiring layer all of which are located in the upper layer of the gate electrode (hereinafter referred to as a subsequent stage input gate 21 (a first gate electrode)) of the subsequent stage logic cell 20 that becomes the verification object. The second wiring layer is formed on the first wiring layer, and the third wiring layer is formed on the second wiring layer. The metallic wiring is connected from the subsequent stage input gate 21 to the metallic wiring M1 through M5 in this order to a direction of the output terminal (hereinafter referred to as the preceding stage output terminal 11) of the preceding stage logic cell 10. Moreover, the metallic wiring M3 is formed in the third wiring layer, the metallic wiring M2, M4 is formed in the second wiring layer, and the metallic wiring M1, M5 is formed in the first wiring layer. In the process of forming the first wiring layer, the metallic wiring M1 connected to the subsequent stage input gate 21 functions as an antenna for capturing electric charges from the plasma. In the process of forming the second wiring layer, the metallic wiring M2 functions as an antenna. In the process of forming the third wiring layer, the metallic wiring M3 functions as an antenna. In this case, the antenna ratios of the preceding stage input gate 21 and the respective metallic wiring M1 to M3 are verified. However, if the wire length of the metallic wiring is considerably short, then the verification of the antenna ratio with the wiring may be omitted. In the exemplary embodiment, the metallic wiring M1, M2 is assumed to be short, and the verification of the antenna ratios of the preceding stage input gate 21 and the respective metallic wiring M1, M2 is omitted.

The antenna ratio of the subsequent stage input gate 21 and the metallic wiring M3 is found by dividing a wiring area of the metallic wiring M3 by the gate area of the subsequent stage input gate 21. The antenna ratio verification part 251 determines that when the antenna ratio is larger that the antenna criterion 230, the antenna ratio indicates the antenna error. When the antenna ratio verification part 251 determined the antenna error, it computes the gate area insufficient quantity 200 required to make the antenna criterion 230 smaller than or equal to the antenna criterion 230. The gate area insufficient quantity 200 is obtained by subtracting the gate area of the subsequent stage input gate 21 from a quotient obtained by dividing the wiring area of the metallic wiring M3 by the antenna criterion 230.

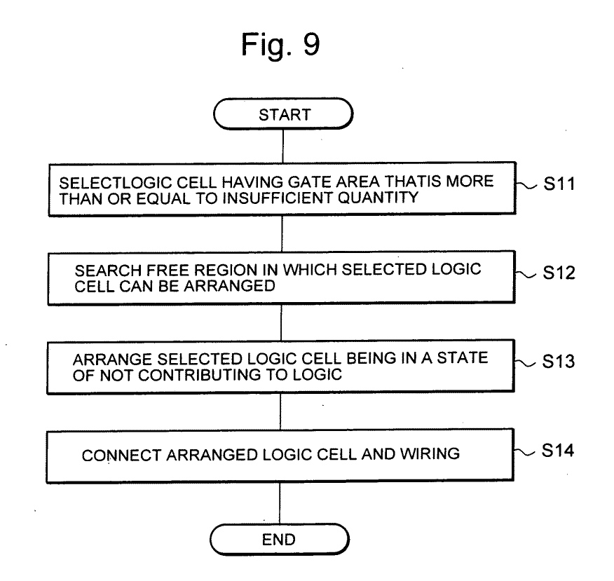

The layout correction part 252 corrects the layout of the design object circuit according to the verification result of the antenna ratio. FIG. 9 is a flow chart showing a layout corrective action in the exemplary embodiment of the design support system 100.

Referring to FIG. 9, the layout correction part 252 selects the logic cell having the gate area more than or equal to the gate area insufficient quantity 200 from the cell library 210 (Step S11). It is desirable to select it with reference to the gate area table 240. By referring to the gate area table 240, it becomes possible to easily select the logic cell having a necessary minimum gate area from among the cell areas of more than or equal to the gate area insufficient quantity 200, and becomes possible to easily select the logic cell of desired cell size and function (circuit element). Moreover, as long as the gate area is more than or equal to the gate area insufficient quantity 200, it is desirable that the logic cell with a smaller cell size is selected on a priority basis.

The logic cells of various gate areas and cell sizes are registered in the cell library 210. For example, as shown in FIG. 13, a plurality of inverter cells different from one another in driving capability are registered as primitive cells in the cell library 210. In the inverter cell, their driving capabilities and gate areas are almost in a proportional relation. The inverter cells of various areas are prepared. Even if the logic cell to be inserted to improve the antenna ratio is not newly prepared, then it is possible to select the logic cell to compensate the gate area insufficient quantity 200.

The layout correction part 252 searches the free regions in which the selected logic cell can be arranged by referring to the layout data 220 (Step S12). First, the free region in which no logic cell is arranged is detected in the design object circuit. Referring to FIG. 7, for example, the layout data 220 includes information that specifies a logic cell arrangement region 30 in which the logic cell is arranged and position coordinates and sizes of free regions B1 to B6. The layout correction part 252 compares the sizes of the free regions B1 to B6 and the size of the selected logic cell and specifies the free region in which the selected logic cell can be arranged. It is assumed that the inverter cell is selected in Step S11, and the plurality of free regions B1 to B5 are specified as the free regions in which the inverter cell concerned can be arranged.

Next, the layout correction part 252 arranges the selected logic cell in the specified free region (Step S13). The logic cell is arranged in the free region as a fill cell 40 (a third logic cell) that performs no logic operations. For example, when arranging the inverter cell, it is arranged in the free region with the output end of the internal inverter being in an open state. When there are a plurality of regions that were specified in Step S12 and enable the inverter cell to be arranged, it is desirable that a free region nearer to the metallic wiring is prioritized and decided as a region in which the logic cell will be arranged.

Here, a position that is desirable as a region in which the fill cell 40 is arranged (position of high priority) will be explained. When connecting the fill cell 40 and the metallic wiring, new metallic wiring is provided between a gate electrode of the transistor in the fill cell 40 in the fill cell (a gate 41 in the fill cell (a second gate electrode)) and the metallic wiring. The metallic wiring functions as a part of antenna connected to the subsequent stage logic cell 20 in the plasma process. When the area of the metallic wiring to be added is large, there is a possibility that the improvement effect of the antenna ratio may fall. In order to control such an increase in the wiring area, it is necessary to arrange the fill cell 40 near the metallic wiring. It is desirable that a free region such that a distance (a wiring path) therefrom to the metallic wiring that can be wired is short is selected as the arrangement region of the fill cell 40 on a priority basis.

Moreover, the metallic wiring connected to the subsequent stage input gate 21 is usually formed sequentially from a lower side wiring layer near the subsequent stage input gate 21. By setting a position of the logic cell to be newly arranged near the metallic wiring provided in the lower layer side wiring layer, it is possible to make the antenna ratio small from the early stage in the manufacture process. In one example shown in FIG. 8, metallic wiring layers M1, M2, and M3 are formed in this order from the wiring layer near the subsequent stage input gate 21. It is desirable that a neighborhood region of the metallic wiring M1 is selected as an region in which the logic cell is arranged with higher priority than a neighborhood region of the metallic wiring M2, and that the neighborhood region of the metallic wiring M2 is selected as an region in which the logic cell is arranged with higher priority than a neighborhood region of the metallic wiring M3.

From the above, a region that can be wired to the metallic wiring provided in the wiring layer near the subsequent stage input gate 21 and whose wiring path thereto is short is selected as the arrangement region of the fill cell 40 on a priority basis. A concrete example will be explained with reference to FIG. 7. For example, let it be assumed that in Step S12, the free region that can be wired to the metallic wiring 11 is not detected, the free regions B1, B2 are detected as the free regions that can be wired to the metallic wiring M2, and the free regions B3 to B5 are detected as the free regions that can be wired to the metallic wiring M3. In this case, the free regions B1, B2 are selected as the arrangement regions of the fill cell 40, being given priority over the free regions B3 to B5. Moreover, since the free region B1 is nearer to the metallic wiring M2 than the free region B2 (the wiring path is shorter), the free region B1 is selected as the arrangement region of the fill cell 40.

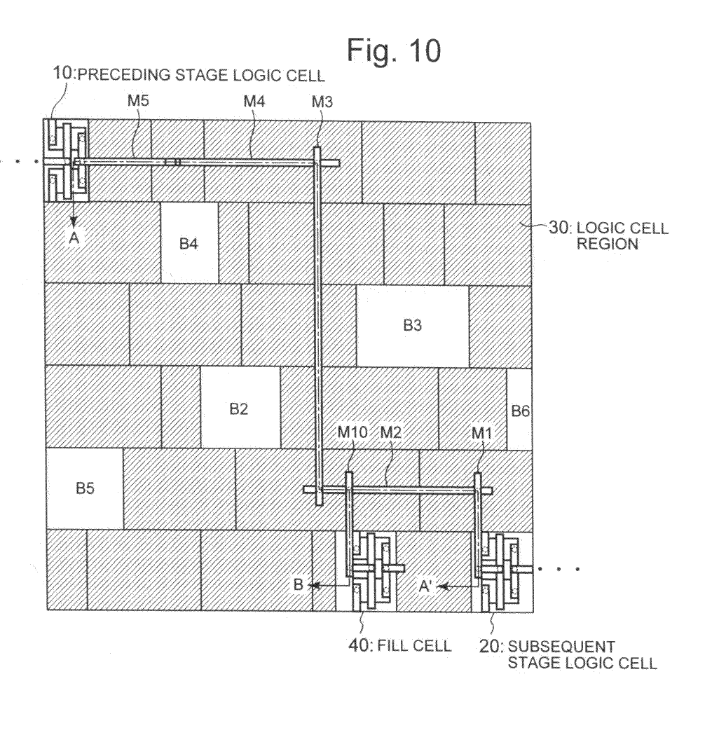

The layout correction part 252 connects the gate 41 in the fill cell 40 arranged in the free region, and the metallic wiring (Step S14). In one example shown in FIG. 10, the input gate of the inverter cell (the gate 41 in the fill cell) arranged in the free region B1 as the fill cell 40 is connected to the metallic wiring M2. The input gate and the metallic wiring M2 are connected through newly arranged metallic wiring M10. By the gate 41 in the fill cell having an area more than or equal to the gate area insufficient quantity 200 being connected to the metallic wiring, the antenna ratio at the time of formation of the metallic wiring M3 becomes less than or equal to the antenna criterion 230, and the antenna error is eliminated.

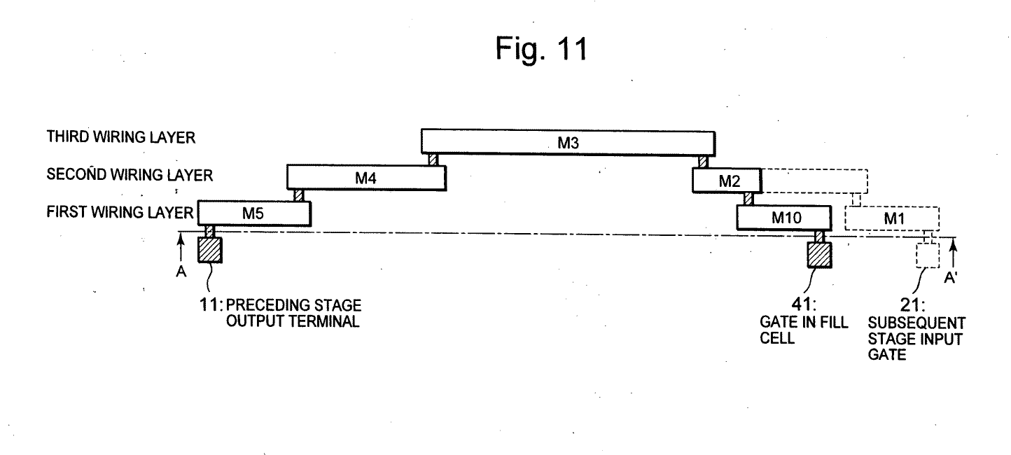

FIG. 11 is a diagram showing an A-A′ section and an A-B section in FIG. 10. Referring to FIG. 11, the gate 41 in the fill cell 40 is connected to the metallic wiring M2 of the second wiring layer through the metallic wiring M10 provided in the first wiring layer. Since the gate 41 in the fill cell is connected to the metallic wiring 2, the antenna ratio at and after a process of forming the second wiring layer becomes a value that considers the gate area of the gate 41 in the fill cell. The antenna ratio can be improved from an early stage in a wiring process by connecting the gate 41 in the fill cell to the metallic wiring on a lower layer side near the subsequent stage input gate 21.

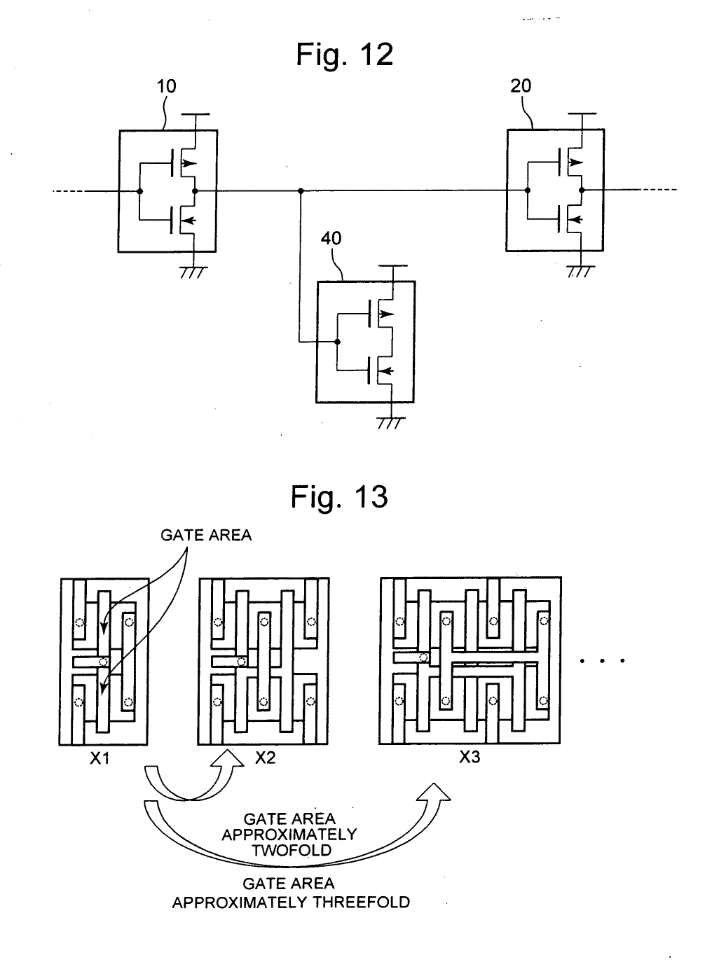

The layout correction part 252 updates the layout data 220 based on the layout pattern corrected as shown in FIG. 10 and FIG. 11. An analysis tool that is not illustrated performs timing verification to a circuit whose layout was corrected using the updated layout data 220. FIG. 12 is equivalent circuit diagrams showing configurations of the preceding stage logic cell 10, of the subsequent stage logic cell 20, and of the fill cell 40, all shown in FIG. 10. Since the metallic wiring (for example, the metallic wiring M3) that sustains the antenna error is long wiring, it has a very large wiring capacitance. On the other hand, an output end of the fill cell 40 connected to the metallic wiring is in an open state, and performs no logic operations. The input capacitance to the fill cell 40 is as small as can be ignored compared with the wiring capacitance. Moreover, in the present invention, since the fill cell is inserted into the free region, the antenna ratio is made to be less than or equal to the antenna criterion 230 without altering the wiring length between the preceding stage logic cell 10 and the subsequent stage logic cell 10 and the layout of arrangement positions of the logic cells, driving capability, etc. The fill cell 40 connected to the metallic wiring causes a very small effect on timings (delay times) of the input signal to the subsequent stage logic cell 20 and of the output signal from the subsequent stage logic cell 20, which results in very small timing variation between before and after the insertion of the fill cell 40. Thus, even if the layout is corrected to eliminate the antenna error, since delay variation is small, timing adjustment after the layout correction can be made easily.

Moreover, since a primitive cell (a standard cell) having a variety of gate areas can be used as the fill cell 40 that is inserted to eliminate the antenna error, it is not necessary to prepare a new cell (e.g., a new diode cell) like the related technology. Furthermore, in the method whereby a cell is inserted and in the method whereby a cell is replaced, like the related technology, it is necessary to select a cell that accords with a function (circuit element) of a cell in which the antenna error arises. It is necessary to prepare the logic cells that are variously different in function and gate area in the related technology. On the other hand, since in the invention of the present application, any logic cell can be used as the fill cell 40 for eliminating the antenna error as long as the cell has the gate area more than or equal to the insufficient quantity, the cell library 210 that is prepared in advance can be used in the circuit design.

In the manufacture process, a mask is formed on a silicon substrate surface using the updated layout data 220, and the semiconductor integrated circuit is produced after processings of etching etc. In the present invention, the logic cell (the fill cell 40) for lightening the plasma damage is inserted into the free region. It is possible to manufacture the semiconductor integrated circuit in which the plasma damage is lightened without increasing a circuit area.

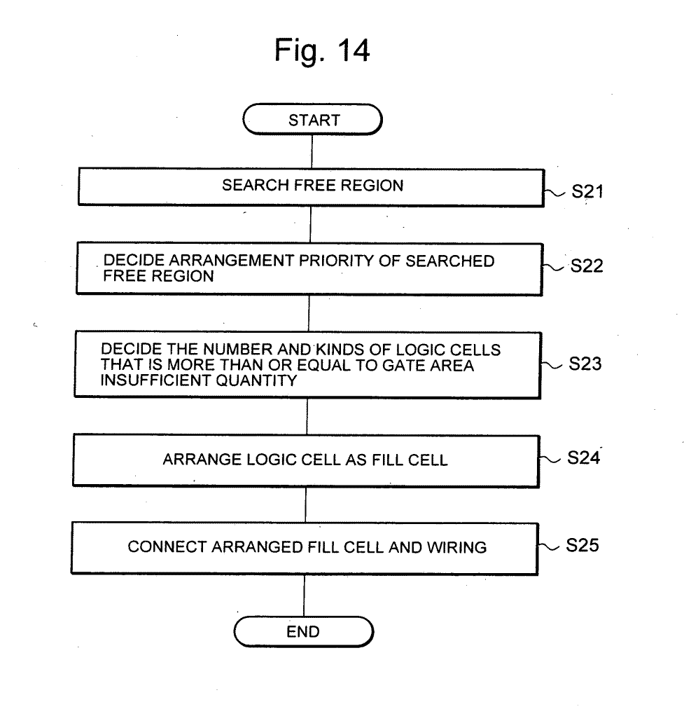

Although in the foregoing, the exemplary embodiments of the present invention have been described in detail, a concrete configuration is not limited to the above-mentioned exemplary embodiments, rather even if it is changed in the range that does not deviate from the gist of the present invention, it is included in the present invention. Although in the exemplary embodiment, the logic cell having the gate area that was more than or equal to the gate area insufficient quantity 200 was selected as the fill cell 40, it does not matter if the fill cells 40 to be added are plural as long as a sum total of their gate areas becomes more than or equal to the gate area insufficient quantity 200. In this case, the layout is corrected, for example, according to the flow shown in FIG. 14.

Referring to FIG. 14, the layout correction part 252 searches the free region on the chip from the layout data 220 (Step S21). Next, arrangement priority of the searched free region is decided (Step S22). Regarding the arrangement priority, it is desirable that the free region that is nearest to the subsequent stage input gate 21 is most highly prioritized, and the next in the similar manner, as in the case described above. The layout correction part 252 refers to the gate area table 240, and selects the logic cells that can be arranged sequentially from the region whose priority is higher until the sum total of the gate areas becomes more than or equal to the gate area insufficient quantity, and decides their number and kinds (Step S23). The layout correction part 252 arranges the decided logic cell in a corresponding free region as the fill cell that performs no logic operations (Step S24). Finally, the layout correction part 252 connects the gate electrode in the arranged fill cell and the metallic wiring within a shortest path (Step S25). By correcting the layout in this way, it is possible to arrange the fill cell for eliminating the antenna error using not uselessly the free regions that are in the shortest path from the metallic wiring.

Further, it is noted that Applicant's intent is to encompass equivalents of all claim elements, even if amended later during prosecution.

What is claimed is:

1. A method of forming a semiconductor integrated circuit, comprising:
providing a first logic cell, a second logic cell and a metallic wiring connected to the first logic cell and a gate electrode of the second logic cell; and
providing a third logic cell including a gate electrode connected to the metallic wiring, such that the third logic cell makes no contribution to a logic operation of the semiconductor integrated circuit, in order that an antenna ratio of the first gate electrode to the metallic wiring does not satisfy an antenna criterion, and an antenna ratio of the first gate electrode and the second gate electrode to the metallic wiring satisfies the antenna criterion.

2. The method according to claim 1, wherein the metallic wiring includes a first metallic wiring arranged in a first wiring layer and a second metallic wiring arranged in a second wiring layer,
wherein the second wiring layer is arranged between the gate electrode of the second logic cell and the first wiring layer,
wherein the third logic cell is arranged in a region nearer to the second metallic wiring than to the first metallic wiring, and
wherein the second gate electrode is connected to the second metallic wiring.

3. The method according to claim 2, wherein the second metallic wiring comprises a metallic wiring that is nearest to the first gate electrode.

4. The semiconductor integrated circuit according to claim 1, wherein the third logic cell includes a logic circuit whose input end is connected to the metallic wiring and whose output end is opened.
